(19) United States
(12) Patent Application Publication
(10) Pub. No.: US 2025/0237946 A1
(43) Pub. Date: Jul. 24, 2025

(54) ORGANOTIN COMPOUND PHOTORESIST COMPOSITION FOR PHOTOLITHOGRAPHY PATTERNING

(71) Applicant: Feng Lu, Irvine, CA (US)

(72) Inventor: Feng Lu, Irvine, CA (US)

(21) Appl. No.: 19/017,730

(22) Filed: Jan. 12, 2025

Related U.S. Application Data
(60) Provisional application No. 63/622,376, filed on Jan. 18, 2024.

(51) Int. Cl. G03F 7/004; G03F 7/20

(52) U.S. Cl. CPC G03F 7/0042; G03F 7/2004

(57) ABSTRACT

An organotin compound photoresist composition for photolithography patterning is described, particularly for extreme ultraviolet radiation (EUV), wherein organotin compound photoresist composition comprises a [n]stannocenophane compound, a solvent, and/or an additive. [n]Stannocenophane contains bridged-stannocenyl group, wherein stannocenyl is bis(cyclopentadienyl)tin, or substituted bis(cyclopentadienyl)tin. Two cyclopentadienyl rings of [n]stannocenophane are connected by n=1, 2, or 3 atom links as intramolecular bridges containing C, Si, Ge, Sn, or O, S, Se, or Te, wherein cyclopentadienyl comprises cyclopentadienyl C₅H₅ group, or substituted cyclopentadienyl C₅H₃R′, C₅H₂R′₂, C₅HR′₃, C₅R′₄, or C₅R′₅ group.

### CROSS REFERENCE TO RELATED APPLICATIONS

This application claims priority to U.S. provisional patent application No. 63/622,376 filed on Jan. 18, 2024 to Lu, entitled “Organotin compound photoresist composition for photolithography patterning”, of which is entirely incorporated herein by reference.

### FIELD OF INVENTION

The present invention relates to organotin compound photoresist composition for photolithography patterning, particularly for extreme ultraviolet lithography (EUV), wherein organotin compound photoresist composition comprises a [n]stannocenophane compound, a solvent, and/or an additive. [n]Stannocenophane contains bridged-stannocenyl group, wherein two cyclopentadienyl rings are connected by n=1, 2, or 3 atom links as intramolecular bridges.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern forming technology using wavelength of 13.5 nm as an exposure light source to manufacture high performance integrated circuits containing high density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light absorption because metals have high absorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Among those promising advanced materials, particularly organometallic tin (organotin) compounds can provide photoresist patterning with significant advantages, such as improved resolution, sensitivity, etch resistance, and lower line width/edge roughness without pattern collapse because of strong EUV radiation absorption of tin, which have been demonstrated.

Organotin compounds have been demonstrated as EUV photoresists, which provide promising approach for the development of further smaller features such as <7 nm.

### SUMMARY

In a first aspect, the present invention pertains to organotin compound photoresist composition for photolithography patterning, particularly for extreme ultraviolet radiation (EUV). The organotin compound photoresist composition comprises a [n]stannocenophane compound, a solvent, and/or an additive. [n]Stannocenophane contains bridged-stannocenyl group, wherein two cyclopentadienyl (Cp) rings of stannocenyl (Cp₂Sn) are connected by n=1, 2, or 3 atom links as intramolecular bridges. The present invention pertains to organic molecules stabilizing organotin photoresists for photolithography patterning. The present invention is to provide improved resolution sensitivity, etch resistance, and lower line width/edge roughness without pattern collapse for photolithography patterning. The additive is organic molecule, including organic thiol, organic alcohol, organic amine, organic amide, organic carboxylic acid, organic phosphine, organic phosphine oxide, or organic phosphonic acid. In addition, [n]stannocenophane compounds also may be used as precursors for the preparation of other organotin photoresists, for example, polymerization of [n]stannocenophane to form organotin polymer as photoresist through ring-opening polymerization (ROP), or with second precursor like water (moisture), oxygen, carbon dioxide, ammonia, borane, or phosphine under ambient condition.

In another aspect, the invention pertains to radiation sensitive [n]stannocenophane compound photoresists. [n]stannocenophane contains bridged-stannocenyl group, wherein two cyclopentadienyl rings are connected by an intramolecular bridges of n=1, 2, or 3 atom links. Stannocenyl comprises bis(cyclopentadienyl)tin, and substituted bis(cyclopentadienyl)tin, wherein cyclopentadienyl comprises cyclopentadienyl C₅H₅ group, or substituted cyclopentadienyl C₅H₃R′, C₅H₂R′₂, C₅HR′₃, C₅R′₄, or C₅R′₅ group with hapticity of η², η³, η⁴, or η⁵ of isomers, wherein R′ is H, a substituted or unsubstituted alkyl, alkenyl, alkynyl, or cycloalkyl group with 1 to 20 carbon atoms, or a substituted or unsubstituted aryl group with 6 to 20 carbon atoms, or an amino, cyano, ether, ester, halide, nitro, silyl, thiol, or carbonyl group.

In a further aspect, the invention pertains to radiation sensitive organotin [n]stannocenophane compound photoresist, wherein [n]stannocenophane compound bearing cyclopentadienyl is one or more selected from the following:

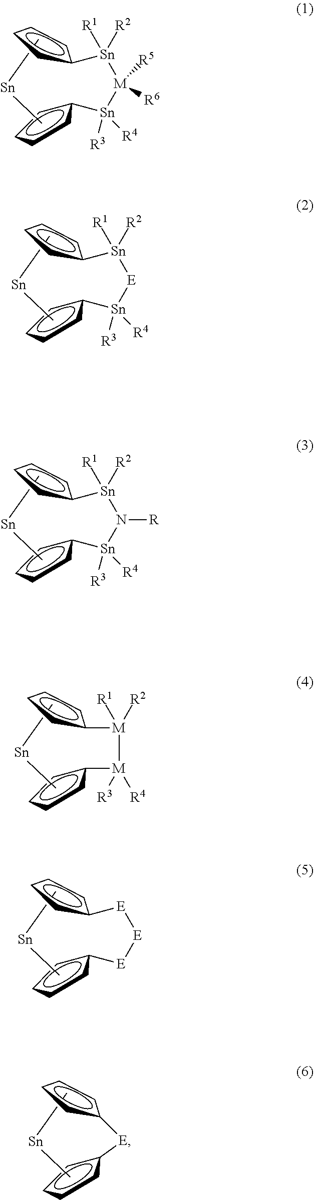

wherein R¹, R², R³, R⁴, R⁵, R⁶ are each independently —R, —ER, —N(R)(R″), —O—(C═O)R, or —NR″—C(═O)R, wherein R, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; M=C, Si, Ge, or Sn; E=O, S, Se, or Te.

The invention relates to radiation sensitive of [n]stannocenophane compound photoresist composition, which can be efficiently patterned after exposure to extreme ultraviolet radiation (EUV), deep ultraviolet radiation (DUV), electron beam radiation, X-ray radiation, or ion-beam radiation, or other likes to form high resolution patterns with low line width roughness, high resolution, low dose and large contrast, such as for <7 nm.

### BRIEF DESCRIPTION OF THE DRAWINGS

FIG. 1 illustrates a flowchart of organotin [n]stannocenophane photoresist radiation photolithography patterning processing over a surface of semiconductor substrate.

### DETAILED DESCRIPTION

The present invention pertains to organotin photoresist composition for photolithography patterning, particularly for extreme ultraviolet radiation (EUV), wherein organotin photoresist composition comprises a [n]stannocenophane compound, a solvent, and/or an additive. [n]stannocenophane compound contains bridged-stannocenyl group, wherein two cyclopentadienyl rings of stannocenyl are connected by an intramolecular bridges of n=1, 2, or 3 atom links, wherein n represents the number of atoms linked two cyclopentadienyl rings. Stannocenyl comprises bis(cyclopentadienyl)tin, or substituted bis(cyclopentadienyl)tin. The present invention is to provide a method of photolithography patterning of [n]stannocenophane compound photoresist composition, particularly, suitable for EUV lithography (e.g. <7 nm). The method of photolithography patterning comprises depositing a [n]stannocenophane compound photoresist composition over a substrate to form a photoresist layer after baking; exposing the photoresist layer to actinic radiation to form a latent pattern; and developing the latent pattern by applying a developer, or sublimation, or vaporization to remove the unexposed or exposed portion of photoresists to form a photolithography pattern. The present invention is further to provide a method of stabilization of [n]stannocenophane compound photoresist by applying organic molecules as additives. [n]stannocenophane compound photoresists may have higher resolution, sensitivity, solubility, stability, shelf life, and lower line width roughness without pattern collapse during microelectronic patterning compared with conventional organic polymer photoresist or inorganic photoresist. Furthermore, [n]stannocenophane compounds may be used precursors to form other organotin photoresists, such as organotin polymers, organotin clusters, or reaction products from the reaction with second precursor like water (moisture), oxygen, carbon dioxide, ammonia, borane, or phosphine under ambient conditions.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched-chain hydrocarbon of 1 to 20 carbon atoms. The term “alkenyl” refers to an aliphatic hydrocarbon of 2 to 20 carbon atoms containing at least one double bond. The term “alkynyl” refers to an aliphatic hydrocarbon of 2 to 20 carbon atoms containing at least one triple bond. The term “cycloalkyl” refers to cyclic aliphatic hydrocarbon of 3 to 20 carbon atoms. The term “cycloalkenyl” refers to substituted and unsubstituted cyclic aliphatic unsaturated organic groups of 3 to 20 carbon atoms including at least one double bond hydrocarbon. The term “aryl” refers to unsubstituted or substituted aromatic group with 6 to 20 carbon atoms.

In some embodiments, cycloalkenyl group comprises substituted and unsubstituted C3 to C8 cyclic aliphatic unsaturated organic groups including at least one double bond, for example,

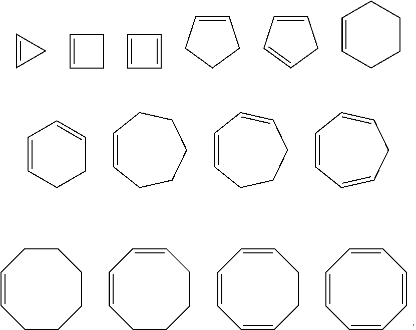

The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like.

The term “amine” refers to primary (—NH₂), secondary (—NHR^{a}), or tertiary (—NR^{a}₂) amine group. The term “cyclic amine” refers to [R^{a}—NH—R^{b}], wherein [R^{a}—R^{b}] is cyclic substituted and unsubstituted C3 to C8 organic group, including, but not limited to:

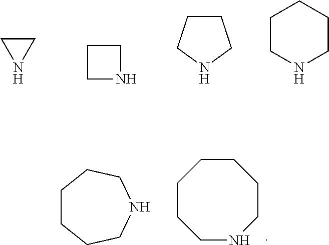

The term “ether” refers to the R^{a}—O—R^{b} group. The term “cyclic ether” refers to the [R^{a}—O—R^{b}], wherein [R^{a}—Re]is cyclic substituted and unsubstituted C3 to C8 organic group, including, but not limited to:

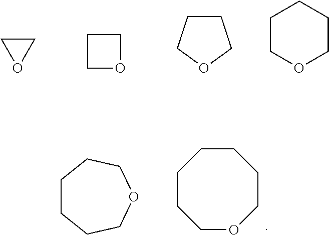

The term “ester” refers to the R^{a}—(C═O)—O—Re group. The term “cyclic ester” refers to the [R^{a}—(C═O)—O—R^{b}], wherein [R^{a}—Re]is cyclic substituted and unsubstituted C4 to C8 organic group, including, but not limited to:

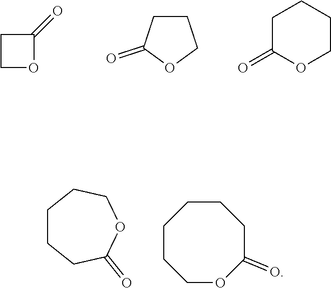

The term “halide” refers to the fluorine (F), chlorine (Cl), bromine (Br), or iodine (I). The term “nitro” refers to the —NO₂. The term “silyl” refers to the —SiR^{a}—, —SiR^{a}₂—, or —SiR^{a}₃ group. The term “thiol” refers to —SH group. The term “carbonyl” refers to the —C═O group. The term “oxo” refers to —O—, or ═O. In the above described, R^{a}, R^{b} are independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms.

In the present disclosure, the term “substituted” refers to replacement of a hydrogen atom with a C1 to C20 alkyl group, a C2 to C20 alkene group, a C2 to C20 alkyne group, a C3 to C20 cycloalkyl group, a C6 to C20 aryl group, or other relevant groups including, but not limited to acid, amide, amine, cyano, cyclic amine, ether, cyclic ether, ester, cyclic ester, halide, imine, nitro, silyl, thiol, or carbonyl group, for example, fluoroalkyl, fluorobenzyl, trifluoroacetic acid.

The terms “η¹” refers to one carbon atom bonded to one metal atom. The terms “η²” refers to two carbon atoms bonded to one metal atom. The terms “η³” refers to three carbon atoms bonded to one metal atom. The terms “η⁴” refers to four carbon atoms bonded to one metal atom. The terms “η⁵” refers to five carbon atoms bonded to one metal atom.

EUV lithography is under the development for the mass production of next generation <7 nm node. EUV photoresists are required to achieve higher performance, higher sensitivity and resolution, and cost reduction.

EUV light has been applied for photolithography at about 13.5 nm. In some embodiments, the EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm, such as 1-3 nm, the conventional chemically amplified (CA) organic polymer photoresists encounter critical issues, such as poor EUV light absorption, low resolution, high line edge roughness (LER), increased pattern collapses and defects. In order to overcome the disadvantages from conventional organic polymer photoresists or inorganic photoresists, novel organometallic photoresists, or organometallic photosensitive compositions, particularly for EUV, have been called for.

Organometallic photoresists are used in EUV lithography because metals have high absorption capacity of EUV radiation. Radiation sensitivity and thermal-, oxygen- and moisture-stability are important for organometallic photoresists. In some embodiments, organometallic photoresists may absorb moisture and oxygen, which may result in decreasing stability, as well as decreasing solubility in developer solutions. In addition, in some embodiments, photoresist layer may outgas volatile components prior to the radiation exposure and/or development operations, which may negatively affect the lithography performance, pattern collapse and increase defects.

In general, metal central plays the key role in determining the absorption of photo radiation. Tin atom provides strong absorption of extreme ultraviolet (EUV) light at 13.5 nm, therein tin cations can be selected based on the desired radiation and absorption cross section.

Meanwhile for organometallic compounds, the organic ligand bonded to tin also has absorption of EUV light. The metal-bonded organic ligands (M-R^{c}, M=metal, R^{c}=cleavable/hydrolysable organic ligands) may also influence the relevant absorption through M-C bonding. Therefore, the tuning and modification of organic ligands can change the resolution, sensitivity and radiation absorption, and the desired control of the material properties.

The bond dissociation energy (BDE) of Sn—C bond determines the light absorption wavelength, corresponding smaller features, and patterned structures.

Organotin photoresists have excellent (e.g., suitable) sensitivity to high energy light (e.g., EUV, DUV, X-ray, or laser) due to tin strong absorption of extreme ultraviolet (EUV) at about 13.5 nm. Accordingly, organotin photoresists have improved sensitivity, resolution, stability compared with conventional organic polymer or inorganic photoresists.

In some embodiments, organotin photoresist comprises small organometallic tin compound, organotin cluster, or organotin polymer with large molecular weight. In some embodiments, the small organometallic tin compound contain one, two, or three tin atoms. In some embodiments, organotin cluster contain more than three tin atoms, for example, twelve.

The organotin photoresists comprise organic ligand, Sn—C bond, or Sn—O bond, or Sn—O—Sn bond providing desirable radiation sensitive and stabilization for photolithography patterning. The organotin photoresists possess excellent properties for photolithographic patterning.

Organotin [n]stannocenophane compound photoresist composition according to embodiments of the present disclosure may have improved etch resistance, sensitivity and resolution, compared with conventional organic polymer or inorganic resists.

Examples of specific organotin [n]stannocenophane compounds as photoresists may be used in implementation of the invention, having a chemical structure bearing stannocenyl or cyclopentadienyl group selected from the following:

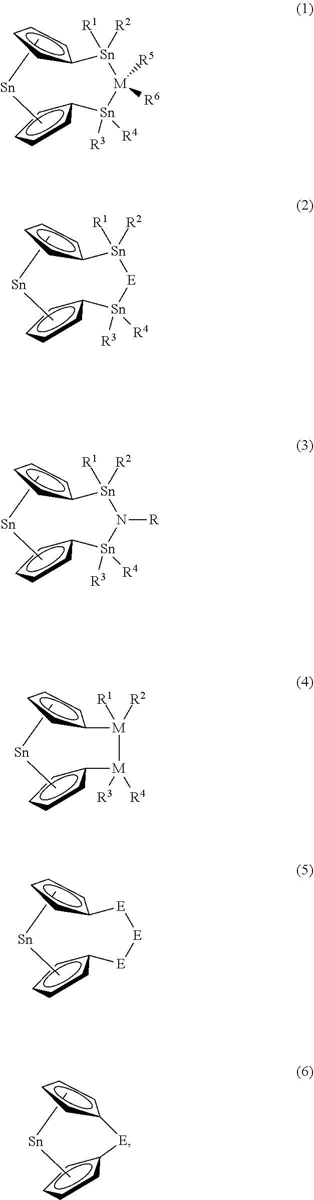

wherein R¹, R², R³, R⁴, R⁵, R⁶ are each independently —R, —ER, —N(R)(R″), —O—(C═O)R, or —NR″—C(═O)R shown as below,

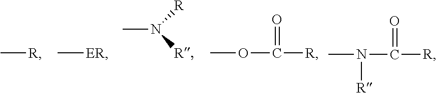

wherein R, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; M=C, Si, Ge, or Sn; E=O, S, Se, or Te.

Wherein cyclopentadienyl comprises cyclopentadienyl C5H₅ group, or substituted cyclopentadienyl C₅H₃R′, C₅H₂R′₂, C₅HR′₃, C₅R′₄, or C₅R's group with hapticity of η², η³, η⁴, or η⁵ of isomers, wherein R′ is H, an alkyl, alkenyl, alkynyl, or cycloalkyl group with 1 to 20 carbon atoms, or an aryl group with 6 to 20 carbon atoms, or an amino, cyano, ether, ester, halide, nitro, silyl, thiol, or carbonyl group.

[n]stannocenophane compound comprises stannocenyl group, wherein stannocenyl comprises bis(cyclopentadienyl)tin, or substituted bis(cyclopentadienyl)tin.

For example, in some embodiments, R¹, R², R³, R⁴, R⁵, R⁶ are each independently alkyl, aryl, or cyclopentadienyl group, wherein cyclopentadienyl comprises cyclopentadienyl C₅H₅, or substituted cyclopentadienyl C₅H₃R′, C₅H₂R′₂, C₅HR′₃, C₅R′₄, or C₅R′₅, wherein R′ is H, methyl, ethyl, n-propyl, iso-propyl, n-butyl, iso-butyl, sec-butyl, t-butyl, phenyl, or benzyl.

For example, in some embodiments, the examples of organotin compounds (5), (6) comprise the following:

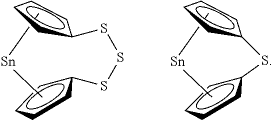

For example, in some embodiments, R¹, R², R³, R⁴, R⁵, R⁶ are each independently H, an alkyl, alkenyl, alkynyl, cycloalkyl, cycloalkenyl, or aryl group, for example, methyl (Me), ethyl (Et), isopropyl (i-Pr), n-butyl (n-Bu), t-butyl (t-Bu), t-amyl, s-butyl, pentyl, hexyl, neopentyl (Neo), cyclohexyl, cyclopentyl, cyclobutyl, cyclopropyl, cyclopentadienyl, phenyl (Ph), or benzyl (Ben) group.

For example, in some embodiments, R¹, R², R³, R⁴, R⁵, R⁶ are each independently alkoxide group, such as —OMe, —OEt, —OPr, —O″—Bu, —O′—Bu, —OPh, or OBen group.

For example, in some embodiments, R¹, R², R³, R⁴, R⁵, R⁶ are each independently amine group, such as —NMe₂, —NEt₂, —NPr₂, —N(″—Bu)₂, —N(′—Bu)₂, or —NPh₂ group.

For example, in some embodiments, R¹, R², R³, R⁴, R⁵, R⁶ are each independently ester group, such as —O—(C═O)Me, —O—(C═O)Et, —O—(C═O)Pr, —O—(C═O)″—Bu, —O—(C═O)′—Bu, or —O—(C═O)Ph.

For example, in some embodiments, R¹, R², R³, R⁴, R⁵, R⁶ are each independently amide group, such as —NH—(C═O)Me, —NH—(C═O)Et, —NH—(C═O)Pr, —NH—(C═O)″—Bu, —NH—(C═O)′—Bu, or —NH—(C═O)Ph.

In the present disclosed patent, organotin [n]stannocenophane compound photoresists comprise cyclopentadienyl group, Sn—C bond, or Sn—C_{cyclopentadienyl} bond, or Sn—O bond, or Sn—S bond, or Sn—Se bond, or Sn—Te bond, or Sn—N bond providing desirable radiation sensitive and stabilization for precursor metal cations. The organotin [n]stannocenophane photoresists possess excellent properties for photolithographic patterning.

As one of ordinary skill in the art will recognize, the organotin [n]stannocenophane compound photoresists listed here are merely intended as illustrated examples of organotin [n]stannocenophane compound photoresists, and are not intended to limit the embodiments to only those organotin [n]stannocenophane compound photoresists specifically described. Rather, any suitable organotin [n]stannocenophane compound photoresist may be used, and all such organotin [n]stannocenophane compound photoresists are fully intended to be included within the scope of the present embodiments.

In one example embodiment, for the preparation of organotin [n]stannocenophane compounds, sandwich bis(cyclopentadienyl)tin or stannocene ((η⁵—C₅H₅)₂Sn, Sc) is used as parent molecule for carrying out lithiation at two C₅ rings by strong bases, for example, methyllithium (MeLi), n-butyllithium (n-BuLi), s-butyllithium (s-BuLi), or t-butyllithium (t-BuLi), and then followed by further procedures to synthesize desired compounds. Stannocene was synthesized according to the reference: C. Janiak, Zeitschrift für Anorganische und Allgemeine Chemie, 2010, 636 (13-14), 2387-2391. For example, in one exemplay embodiment, bi-lithiation at two C₅ rings of stannocene can be carried out by n-BuLi at −78° C. in THF to afford (η⁵—C₅H₄Li)Sn(η⁵—C₅H₄Li) (ScLi₂) depicted as below:

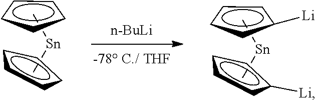

which is according to the references, A. H. Cowley, P. Jutzi, F. X. Kohl, J. G. Lasch, N. C. Norman, E. Schliter, “Sequential Lithiation and Silylation of Stannocene”, Angew. Chemie International Edition 23 (1984), 8, 616-617; A. H. Cowley, J. G. Lasch, N. C. Norman, C. A. Stewart, and T. C. Wright, “Lithiation and Derivatization of Group 4A Bent-Sandwich Molecules”, Organometallics 1983, 2, 1691-1692, all of which are incorporated herein by references. In some embodiments, the addition of coordination reagents is required to improve the yields of bi-lithiation at two C₅ rings, for example, (N,N,N′,N′-tetramethyl-1,2-diaminotheane (TMEDA). A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In the present disclosure, in one exemplary embodiment, the organotin ansa-bridged [n]stannocenophane compound can be prepared according to the following strategy:

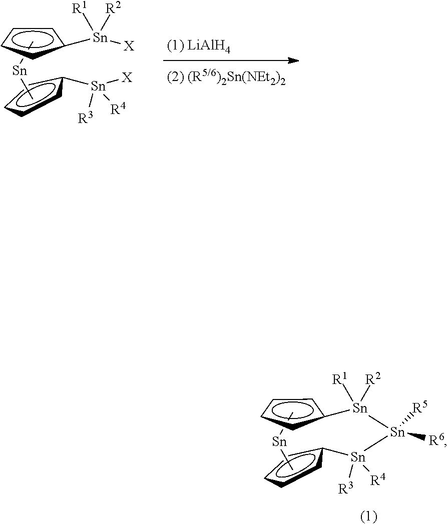

wherein R¹, R², R³, R⁴, R⁵, R⁶ are each independently —R, —ER, —N(R)(R″), —O—(C═O)R, or —NR″—C(═O)R, wherein R, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; M=C, Si, Ge, or Sn; E=O, S, Se, or Te; X=F, Cl, Br, or I. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In another exemplary embodiment, the organotin ansa-bridged [n]stannocenophane compounds may be prepared according to the following strategy:

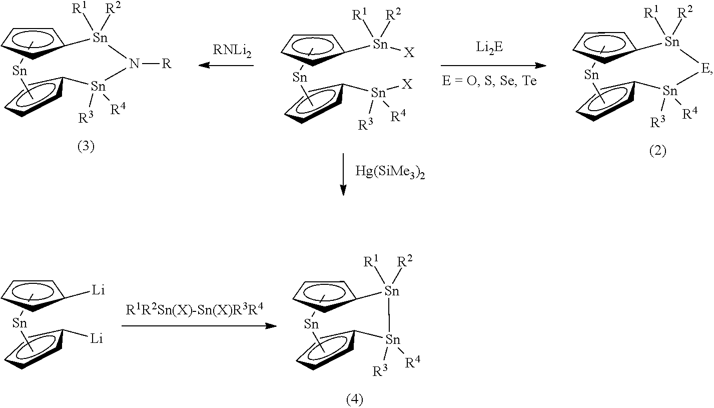

wherein R¹, R², R³, R⁴ are each independently —R, —ER, —N(R)(R″), —O—(C═O)R, or —NR″—C(═O)R, wherein R, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; E=O, S, Se, or Te; X=F, Cl, Br, or I. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In further exemplary embodiment, the organotin ansa-bridged [n]stannocenophane compound can be prepared according to the following strategy:

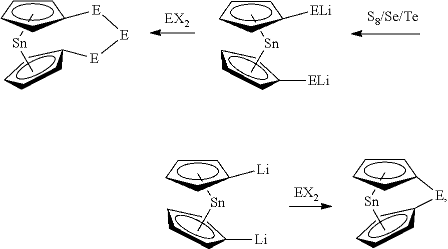

wherein E=S, Se, or Te; X=F, Cl, Br, or I. [(η⁵—C₅H₄ELi)₂Sn (Sc-(ELi)₂, E=S, Se, or Te) was prepared through the reaction of [(η⁵—C₅H₄Li]₂Sn with elemental sulfur, selenium, or tellurium under ambient conditions, which is according to similar manner of the reference: C. Elschenbroich, F. Lu, O. Burghaus, K. Harms, and J. Pebler, Zeitschrift für Anorganische und Allgemeine Chemie, 2011, 637, 1750-1755. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

The invention pertains to the methods for preparation and purification of organotin [n]stannocenophane compounds. The methods for purification include, but not limited to, distillation, extraction, filtration, recrystallization, column chromatography, coordination, sublimation, vaporization, or combinations thereof.

The organotin [n]stannocenophane compounds contain Sn—C, or Sn—N, or Sn—O, or Sn—S, or Sn—Se, or Sn—Te bond with different bond dissociation energy (BDE) and sensitivity to extreme ultraviolet light.

The organotin [n]stannocenophane compounds contain cyclopentadienyl C₅H₅, or substituted cyclopentadienyl C₅H₃R′, C₅H₂R′₂, C₅HR′₃, C₅R′₄, or C₅R′₅ group with hapticity of η¹, η², n³, n⁴ or η⁵ of isomers, wherein R′ is H, a substituted or unsubstituted alkyl, alkenyl, alkynyl, or cycloalkyl group with 1 to 20 carbon atoms, or a substituted or unsubstituted aryl group with 6 to 20 carbon atoms. For example, R′ is methyl, ethyl, isopropyl, n-butyl, t-butyl, t-amyl, s-butyl, pentyl, hexyl, neopentyl, cyclohexyl, cyclopentyl, cyclobutyl, cyclopropyl, phenyl, or benzyl group.

Cyclopentadienyl group (C₅R₅, or Cp) may impart photosensitivity to the compounds. The formed Cp-Sn bond may promote suitable solubility in organic solvent to cyclopentadienyl-containing organotin compound photoresist. Accordingly, Cp-Sn bond containing organotin compound photoresist, according to an embodiment, may have improved sensitivity, resolution, etch resistance, and stability, and may suitable for EUV photoresists, and/or the precursors for EUV lithography to form tin-containing film like tin oxide or tin oxide hydroxide film.

The present organotin [n]stannocenophane compounds contain cyclopentadienyl-Sn bond (Cₚ—Sn bond). Cₚ—Sn bond is sensitive to UV light and occurs the radiation disruption to generate free radical when exposures to UV light, which has been demonstrated, for example, P. J. Baker, A. G. Davies, M.-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅″ radical. This study demonstrated cyclopentadienyl (C₅H₅) group or substituted cyclopentadienyl (C₅R₅) group has higher UV light photosensitivity compared with alkyl (e.g., methyl, butyl) group under identical condition. This property is beneficial to decrease EUV light dose and increase resolution.

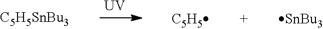

The organotin [n]stannocenophane compounds contain tin and C—Sn bond, therefore may absorb extreme ultraviolet light at 13.5 nm. The organotin [n]stannocenophane compound photoresists contain cyclopentadienyl (Cₚ), or substituted-cyclopentadienyl group, π bond, C—Sn bond and related interaction and may have excellent sensitivity to high energy light (e.g., EUV) due to tin absorption high energy EUV ray at 13.5 nm. Accordingly, [n]stannocenophane compound photoresists may have improved sensitivity, resolution, and stability compared with conventional organic polymer photoresist or inorganic photoresist.

The organotin [n]stannocenophane compound photoresists may have excellent sensitivity to EUV radiation light due to the tin absorption high energy EUV ray at 13.5 nm (low expose dose photoresist, e.g., <20 mJ/cm²), and the disruption of Cp-Sn bond to form free radical, tin oxide and relative products, and toughness; low or free pattern defectivity at nanoscale. Accordingly, the solution composition of organotin [n]stannocenophane compound photoresists may have tight pitch (e.g., <10 nm), and may sustain the yield and deliver high resolution.

The organotin [n]stannocenophane compound photoresists bearing unsaturated cycloalkenyl group and C_{cycloalkenyl}—Sn bond, e.g., cyclopentadienyl or substituted-cyclopentadienyl group, according to embodiments of the present disclosure, may have improved etch resistance, sensitivity, and resolution, compared with C_{alkyl}—Sn containing organotin photoresist.

The organotin [n]stannocenophane compound photoresist composition according to embodiments of the present disclosure may have improved etch resistance, sensitivity and resolution, compared with conventional organic polymer photoresists and inorganic photoresists, wherein oxygen, nitrogen, or various groups are bonded to tin metal as described above.

The organotin [n]stannocenophane compound photoresists are soluble in appropriate organic solvents for further photolithography pattern processing. The solution of organotin [n]stannocenophane compound photoresist can be formed by dissolving in organic solvents, including but not limit to, methylene chloride, chloroform, tetrahydrofuran, dimethoxyethane, dimethylformamide, dimethyl sulfoxide, alcohols (e.g., 4-methyl-2-pentenol, ethanol, methanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. The solution composition of organotin [n]stannocenophane compound can be utilized as EUV photoresist composition for further processing and patterning. A person of ordinary skills in the art will recognize that the choice of solvents and solution composition components within the explicit ranges of above are contemplated and are within the present disclosure.

The organotin [n]stannocenophane compound photoresist composition may include 0.1 wt % to 30 wt % of organotin [n]stannocenophane compound, based on the total weight of the organotin [n]stannocenophane compound photoresist composition. A person of ordinary skills in the art will recognize that the samples, concentrations, and amounts of organotin [n]stannocenophane compound within the explicit ranges of above are contemplated and are within the present disclosure.

In general, the poor stability of organotin or organotin cluster photoresists in solution after aged would lead to aggregation or precipitation with short shelf life for photolithography, which then would result in scums or defects in photolithography patterning. In some embodiments, the addition of organic additive may increase the stability of the radiation sensitive organotin [n]stannocenophane compound photoresist composition.

In some embodiments, the hydrolysable or cleavable ligands of organotin compound, cluster, or polymer photoresist precursors carry out hydrolysis with water or moisture from promoting agent to form free hydroxyl (—OH) groups, and then condensation to form organotin clusters. For example, in some embodiments, in situ hydrolysis of organometallic precursors form organometallic dimer represented by (RₙM)₂(OH)₂L₄₋ₙ(H₂O)₂ (M=metal, R=organic ligand). The aggregation of organotin clusters or polymers in the presence of organometallic dimer bearing free —OH groups is prevented due to the complete hydrolysis of organometallic dimer. The aggregation of organotin clusters or polymers would bridge over proximate resist patterns and then lead to scum.

In some embodiments, the stability of [n]stannocenophane compound photoresists in solution can be improved by organic molecules as stabilizers. The organic molecules-stabilized [n]stannocenophane compound photoresists possess improved solubility, uniformity, or shelf life for photolithography patterning.

In some embodiments, organic molecule as stabilizing additive includes, but not limited to, organic thiol, organic alcohol, organic amine, organic amide, organic carboxylic acid, organic phosphine, phosphine oxide, or organic phosphonic acid, or a combination thereof. A person of ordinary skills in the art will recognize that organic molecules, concentrations, and solution composition components within the explicit ranges of above are contemplated and are within the present disclosure.

In some embodiments, organic thiol includes, but not limited to, 1-dodecanethiol, 2-dodecanethiol, 1,12-dodecanedithiol, 1-docosanethiol, 1-decanethiol, 1-heptanethiol, 2-heptanethiol, 1-heptadecanethiol, 1-hexanethiol, 1-hexadecanethiol, 1-nonanethiol, 1-octadecanethiol, 1-octanethiol, 1-pentadecanethiol, 1-tetradecaenthiol, 1-tridecanethiol, 1-undecanethiol, 1,8-octanedithiol, 1,2-ethanedithiol, or a combination thereof.

In some embodiments, organic alcohol includes, but not limited to, 1-dodecanol, 1-octanol, 1-hexadecanol, 1-heptanol, 1-heptadecanol, 1-decanol, 1-undecanol, 1-dodecanol, 1-tridecanol, 1-tetradecaonl, 1-nonaol, 1,10-decanediol, 1,2-hexadecanediol, 1,12-dodecanediol, 1,8-octanediol, 1,11-undecanediol, 2-mercaptoethanol, or a combination thereof.

In some embodiments, organic amine includes, but not limited to, 1-heptadecyloctadecylamine, decylamine, dodecylamine, heptylamine, heptadecylamine, hexadecylamine, isotridecanamine, nonylamine, octadecylamine, octanamine, octylamine, pentadecylamine, tetradecylamine, tridecylamine, triethylamine, undecylamine, undecanamine, 1,8-diaminooctane, 1,9-diaminononane, 1,12-dodecanediamine, 1,11-undecanediamine, or a combination thereof.

In some embodiments, organic amide includes, but not limited to, decanamide, docosanamide, dodecanamide, heanoamide, heptanamide, heptadecanamide, hexadecanamide, icosanamide, nonanamide, nonadecanamide, nonaediamide, octanamide, oleamide, octadecanamide, octanediamide, pentadecanamide, tetradecanamide, tridecanamide, undecanamide, or a combination thereof.

In some embodiments, organic carboxylic acid includes, but not limited to, oleic acid, citric acid, decanoic acid, hexadecanedioic acid, lauric acid, nonanoic acid, octanoic acid, palmitic acid, suberic acid, undecanoic acid, 1,11-undecanedicarboxylic acid, thiolglycolic acid, mercaptoacetic acid, mercaptopropionic acid, or a combination thereof.

In some embodiments, organic phosphine, phosphine oxide, or phosphonic acid, include, but not limited to, trioctylphosphine, tributylphosphine, tris(dimethylamino)phosphine, tris(diethylamino)phosphine, trioctylphospine oxide, hexylphosphonic acid, octadecylphosphonic acid, 11-undecenyl phosphonic acid, or a combinations thereof.

In some embodiments, organotin compound photoresists may comprise functional groups, including but not limited to, amine, amide, cyano, carbonyl, carboxylic acid, ether, halogen, hydroxy, keto, thiol, silyl, or combinations thereof.

In some embodiments, organic molecules additive stabilizers may be adsorbed, grafted, immobilized, anchored, or coordinated on [n]stannocenophane compound photoresists as supports.

In some embodiments, the organic molecules stabilized [n]stannocenophane compound photoresist composition according to an embodiment is prepared by the addition of organic molecular stabilizer to the solution of [n]stannocenophane compound under ambient condition. A person of ordinary skills in the art will recognize that the temperatures, or addition manner within the explicit ranges of above are contemplated and are within the present disclosure.

The organotin [n]stannocenophane compound photoresist composition can be utilized for photolithography patterning including extreme ultraviolet radiation (EUV) (13.5 nm), deep ultraviolet radiation (DUV) such as KrF excimer laser (248 nm) or ArF excimer laser (193 nm), e-beam radiation, X-ray radiation, or ion-beam radiation for further processing and patterning.

The present invention encompasses organotin compound photoresist composition for photolithography patterning. The general photolithography process comprises: (1) forming an organotin compound photoresist composition; wherein the organotin photoresist composition comprises a [n]stannocenophane compound, a solvent, and/or an additive; [n]stannocenophane compound photoresist may be stabilized by organic molecules additives; (2) the formed [n]stannocenophane compound photoresist composition is then deposited over a substrate such as silicon, silicon oxide to form photoresist layer; (3) after baking at appropriate temperature; (4) the [n]stannocenophane compound photoresist layer is exposed to actinic radiation to form a latent pattern; (5) the formed latent pattern is developed by applying a developer (e.g., aqueous basic/acid solutions, or organic solvents), or sublimation, or vaporization to remove the selected portion of photoresists; (6) to form a photolithography pattern.

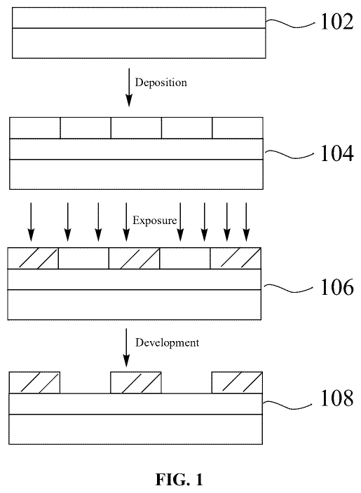

In the present disclosure, a method of forming photolithography pattern using the organotin [n]stannocenophane compound photoresist composition is illustrated by FIG. 1. The general photolithography process described by FIG. 1, is to deposit photoresist over a substrate 102 to form a thin photoresist layer 104; after pre-exposure baking, the formed layer is exposed to actinic radiation to form a latent image 106; after post-exposure baking, the latent is developed by the appropriate developer, such as aqueous basic/acid solutions or organic solvents, to produce the developed resist photolithography pattern 108.

In an embodiment, organotin [n]stannocenophane compound photoresist is deposited on a surface of semiconductor substrate by wet deposition like spin-on coating, spray coating, dip coating, or knife edge coating. In another embodiment, organotin [n]stannocenophane compound photoresist is deposited by dry deposition like chemical vapor deposition (CVD), atomic layer deposition (ALD), physical vapor deposition (PVD), or the like over the surface of substrate.

In some embodiments, after exposure to extreme ultraviolet light, ultraviolet light, e-beam radiation, X-ray radiation or other likes, the components or properties of organotin [n]stannocenophane compound photoresist may change between exposed and unexposed portions. After development, the exposed or unexposed portions of organotin [n]stannocenophane compound photoresist may be removed by appropriate wet or dry developer, such as organic solvent or aqueous solution. Organic ligands of organotin [n]stannocenophane compound photoresists can be cleaved to form metal oxide or polynuclear oxo/hydroxo network patterns or the like. The exposed or unexposed portion of photoresists can be removed by the developer based on different features, solubility and properties. In some embodiments, the developer is a wet developer such as organic solvent, or aqueous solution.

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), methylene chloride, chloroform, aromatic solvents (e.g., benzene, toluene, xylene), acid (e.g., formic acid, acetic acid, oxalic acid, 2-ethylhexanonic acid), and combinations thereof.

In some embodiments, the wet liquid solvent developing process is applied by dipping the exposed/unexposed substrates into a developer bath. In some embodiments, the wet solvent developing solution can be sprayed into the exposed/unexposed photoresists layer.

In some embodiments, the developer is a dry developer including, but not limited to, Cl₂, CH₂Cl₂, BF₃, BCl₃, CF₄, CCl₄, HBr, or a combination thereof.

In some embodiments, the developing method is sublimation or vaporization under reduced pressure (e.g. in the range of 0.0001 torr to 100 torr), and/or high temperature (e.g. in the range of 20 to 300° C.).

In some embodiments, the stability, solubility, and uniformity of organotin [n]stannocenophane compound photoresist composition may be improved, and dissolution during a photolithography such as EUV or DUV. Accordingly, a photolithography pattern having improved stability, solubility, sensitivity and resolution may be afforded by using of [n]stannocenophane compound photoresist. Additionally, the as-formed pattern by using of [n]stannocenophane compound photoresist composition may not form scums and defects.

In addition, organotin [n]stannocenophane compound photoresist compositions for photolithography patterning according to an embodiment is not necessarily limited to the negative tone image but may be formed to have a positive tone image.

Organotin [n]stannocenophane compound photoresists have advantages compared with conventional organic polymer photoresists or inorganic photoresists. However, it will be understood that not all the advantages have been necessarily discussed herein to include all embodiments or examples, other embodiments or examples may offer different advantages.

Hereinafter, the present invention is described in more details through Examples regarding the preparation of [n]stannocenophane compounds as photoresists for photolithography patterning. However, the present invention is not limited by the Examples. The following examples are provided for further illustration of certain embodiments of the disclosure, which is not necessarily limited to these embodiments.

### EXAMPLES

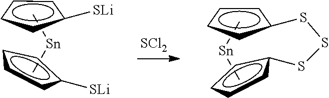

Synthesis of (η⁵-C₅H₄)]₂Sn(S)₃. At 0° C., to a solution of Sc-(SLi)₂ (330 mg, 1.02 mmol) in DME (100 mL), freshly distilled SCl₂ (0.07 mL, 1.1 mmol) in Et₂O (10 mL) was added dropwise with vigorously stirring. After stirred for hours, all the volatiles were removed in vacuum, the residue was extracted by toluene and filtered through Celite. The filtrate was then evaporated in vacuum to give the titled product. Yield: 212 mg, 60%. MS (EI): m/z 343 (M+).

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the spirit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin compound photoresist, having a chemical structure bearing stannocenyl group represented by the following: 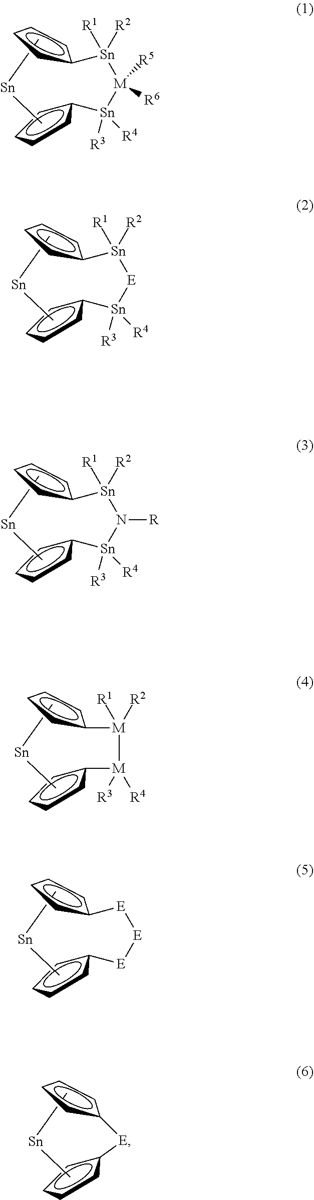
wherein R¹, R², R³, R⁴, R⁵, R⁶ are each independently —R, —ER, —N(R)(R″), —O—(C═O)R, or —NR″—C(═O)R, wherein R, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; M=C, Si, Ge, or Sn; E=O, S, Se, or Te.

2. The organotin compound photoresist of claim 1, wherein stannocenyl is bis(cyclopentadienyl)tin, or substituted bis(cyclopentadienyl)tin, wherein cyclopentadienyl comprises cyclopentadienyl C₅H₅group, or substituted cyclopentadienyl C₅H₃R′, C₅H₂R′₂, C₅HR′₃, C₅R′₄, or C₅R's group with hapticity of η¹, η², η³, η⁴, or η⁵ of isomers, wherein R′ is H, a substituted or unsubstituted alkyl, alkenyl, alkynyl, or cycloalkyl group with 1 to 20 carbon atoms, or a substituted or unsubstituted aryl group with 6 to 20 carbon atoms.

3. The organotin compound photoresist of claim 1, wherein M=Sn.

4. The organotin compound photoresist of claim 1, wherein R¹, R², R³, R⁴ are each independently —R, —ER, —N(R)(R″), —O—(C═O)R, or —NR″—C(═O)R, wherein R, R″ are each independently H, alkyl, or aryl.

5. The organotin compound photoresist of claim 1, wherein R⁵, R⁶ are each independently —R, —ER, —N(R)(R″), —O—(C═O)R, or —NR″—C(═O)R, wherein R, R″ are each independently H, alkyl, or aryl.

6. The organotin compound photoresist of claim 2, wherein R′ is H, methyl, ethyl, propyl, n-butyl, t-butyl, phenyl, or benzyl.

7. The organotin compound photoresist of claim 1, wherein the photoresist is a photoresist for extreme ultraviolet radiation, deep ultraviolet radiation, e-beam radiation, X-ray radiation, or ion-beam radiation photolithography.

8. An organotin compound photoresist composition, comprising a [n]stannocenophane compound, a solvent, and an additive.

9. The organotin compound photoresist composition of claim 8, wherein the [n]stannocenophane compound bearing stannocenyl group is one or more selected from the following: 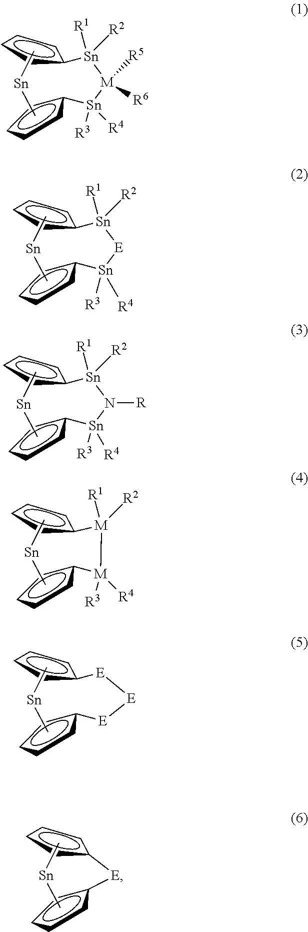
wherein R¹, R², R³, R⁴, R⁵, R⁶ are each independently —R, —ER, —N(R)(R″), —O—(C═O)R, or —NR″—C(═O)R, wherein R, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; M=C, Si, Ge, or Sn; E=O, S, Se, or Te.

10. The organotin compound photoresist composition of claim 9, wherein stannocenyl is bis(cyclopentadienyl)tin, or substituted bis(cyclopentadienyl)tin, wherein cyclopentadienyl comprises cyclopentadienyl C₅H₅ group, or substituted cyclopentadienyl C₅H₃R′, C₅H₂R′₂, C₅HR′₃, C₅R′₄, or C₅R′₅ group with hapticity of η¹, η², η³, η⁴, or η⁵ of isomers, wherein R′ is H, a substituted or unsubstituted alkyl, alkenyl, alkynyl, or cycloalkyl group with 1 to 20 carbon atoms, or a substituted or unsubstituted aryl group with 6 to 20 carbon atoms.

11. The organotin compound photoresist composition of claim 9, wherein M=Sn; E=O, S, or Se.

12. The organotin compound photoresist composition of claim 9, wherein R¹, R², R³, R⁴ are each independently —R, —ER, —N(R)(R″), —O—(C═O)R, or —NR″—C(═O)R, wherein R, R″ are each independently H, alkyl, or aryl.

13. The organotin compound photoresist composition of claim 9, wherein R⁵, R⁶ are each independently —R, —ER, —N(R)(R″), —O—(C═O)R, or —NR″—C(═O)R, wherein R, R″ are each independently H, alkyl, or aryl.

14. The organotin compound photoresist composition of claim 9, wherein R, R″ are each independently H, a methyl, ethyl, propyl, n-butyl, t-butyl, phenyl, or benzyl group.

15. The organotin polymer photoresist composition of claim 8, wherein the additive comprises organic thiol, organic alcohol, organic amine, organic amide, organic carboxylic acid, organic phosphine, organic phosphine oxide, or organic phosphonic acid.

16. A method for photolithography patterning, comprising:
depositing an organotin compound photoresist composition over a substrate; wherein the organotin compound photoresist composition comprises a [n]stannocenophane compound, a solvent and an additive;
exposing the organotin photoresist layer to actinic radiation to form a latent pattern; and
developing the latent pattern by applying a developer, or sublimation, or vaporization to remove the unexposed or exposed portion of photoresists to form a photolithography pattern.

17. The method of claim 16, wherein the [n]stannocenophane compound bearing cyclopentadienyl group is one or more selected from the following: 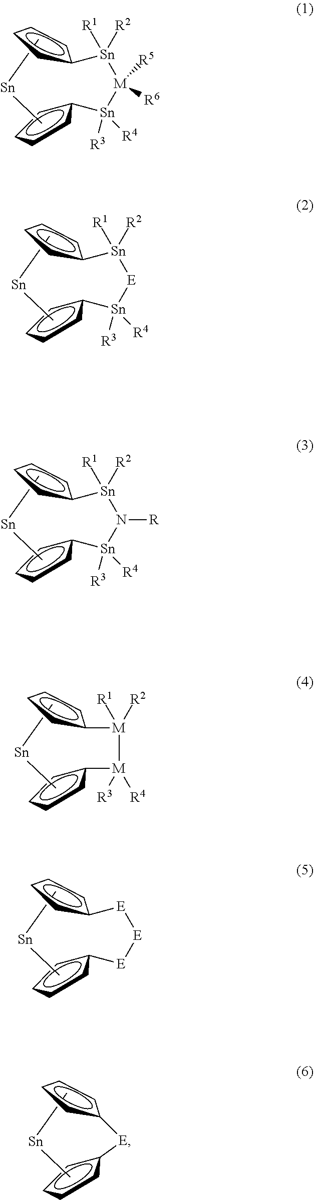
wherein R¹, R², R³, R⁴, R⁵, R⁶ are each independently —R, —ER, —N(R)(R″), —O—(C═O)R, or —NR″—C(═O)R, wherein R, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; M=C, Si, Ge, or Sn; E=O, S, Se, or Te.

18. The method of claim 17, wherein cyclopentadienyl comprises cyclopentadienyl C₅H₅ group, or substituted cyclopentadienyl C₅H₃R′, C₅H₂R′₂, C₅HR′₃, C₅R′₄, or C₅R′₅ group, wherein R′ is H, a substituted or unsubstituted alkyl, alkenyl, alkynyl, or cycloalkyl group with 1 to 20 carbon atoms, or a substituted or unsubstituted aryl group with 6 to 20 carbon atoms.

19. The method of claim 17, wherein M=Sn; E=O, S, Se, or Te.

20. The method of claim 17, wherein R¹, R², R³, R⁴, R⁵, R⁶ are each independently —R, —ER, —N(R)(R″), —O—(C═O)R, or —NR″—C(═O)R, wherein R, R″ are each independently H, alkyl, or aryl.
